(19) United States
(12) Patent Application Publication
(10) Pub. No.: US 2013/0220420 A1
(43) Pub. Date: Aug. 29, 2013

(54) METHOD FOR THE WET-CHEMICAL ETCHING BACK OF A SOLAR CELL EMITTER

(71) Applicants: Agata Lachowicz, Karlstein (DE); Berthold Schum, Biebergemuend (DE); Knut Vaas, Alzenau (DE)

(72) Inventors: Agata Lachowicz, Karlstein (DE); Berthold Schum, Biebergemuend (DE); Knut Vaas, Alzenau (DE)

(73) Assignee: SCHOTT SOLAR AG, Mainz (DE)

(21) Appl. No.: 13/820,538

(22) PCT Filed: Sep. 2, 2011
(86) PCT No.: PCT/EP2011/065229

§ 371 Date: May 13, 2013

(30) Foreign Application Priority Data
Sep. 3, 2010 (DE) 10 2010 037 311.7
May 3, 2011 (DE) 10 2011 050 055.3

(51) Int. Cl. H01L 31/18

(52) U.S. Cl. CPC H01L 31/18
USPC 136/261; 438/753

(57) ABSTRACT

A method for the wet-chemical etching of a solar cell emitter is provided. The method performs homogeneous etching using an alkaline etching solution containing at least one oxidizing agent selected from the group consisting of peroxodisulphates, peroxomonosulphates and hypochlorite.

The invention relates to a method for the wet-chemical etching back of a highly doped silicon layer in an etching solution, the silicon layer having a dopant concentration of 10¹⁸ atoms/cm³, in particular >10¹⁹ atoms/cm³, and the highly doped silicon layer being a surface region of an emitter of a crystalline solar cell.

In crystalline solar cells according to the prior art, the emitter can be produced in a high-temperature step by in-diffusion of phosphorus. Low-doped p-type silicon (the concentration of the dopant is on the order of 10¹⁶ atoms/cm³)—generally with boron as base doping—is used as the starting material. The uppermost layer of the emitter is highly doped; that is, the concentration of the dopant is generally greater than 10¹⁸ atoms/cm³, in particular greater than 10¹⁹ atoms/cm³.

The metal contacts on the front side are produced predominantly by means of thick-film silver pastes in the silk-screen printing process with subsequent sintering. On the one hand, a high phosphorus surface concentration is advantageous for the creation of a low-ohmic contact between the silver paste and the emitter; on the other hand, such a high surface concentration of the doping agent causes more enhanced recombination of the charge carrier pairs and, as a result, a reduced short-circuit current in the solar cell (reduced blue sensitivity).

Depending on the type of doping agent, its introduction, and the diffusion process employed, the phosphorus surface concentration can exceed the solubility limit of phosphorus in silicon (approximately 5×10²⁰ atoms/cm³). This leads to the formation of a separate phase having the composition SiₓP_{y} or SiₓP_{y}O_{z}, which in the course of diffusion, crystallizes out in the form of needle-shaped precipitates in the emitter itself or on the emitter surface. The precipitates and their interfaces with the silicon matrix constitute additional recombination centers (see P. Ostoja et al., “The Effects of Phosphorus Precipitation on the Open-Circuit Voltage in n+/p Silicon Solar Cells,” Solar Cells 11 (1984), 1-12). Moreover, the precipitates can give rise to dislocations and defects in lower-lying crystal zones, which likewise influence efficiency.

The surface concentration of the dopant can, as mentioned, be influenced in part by the choice of the doping agent, the introduction of the doping agent, and the diffusion process, in part by thermal oxidation (thermal etching) as well as wet-chemical etching/cleaning steps after diffusion.

The wet-chemical processes after diffusion generally consist of a sequence of etching and cleaning steps. Usually, a dilute HF solution for removal of the phosphosilicate glass layer and an alkaline emitter etching solution or acidic cleaning solution are employed.

Optionally, edge isolation, that is, the electrical separation of emitter region and base region of the solar cell can also be carried out by wet chemistry. A mixture of nitric acid and hydrofluoric acid can be used for this, possibly with further additives, such as acids. Afterwards, parasitically formed porous silicon can be removed using a strongly alkaline solution (such as NaOH or KOH).

Typical alkaline emitter etching solutions are based on ammonia or ammonia derivatives and water peroxide. By way of example, reference is made to the “SC1 solution” of the RCA cleaning developed for semiconductor manufacture (W. Kern, “The Evolution of Silicon Wafer Cleaning Technology” in J. Electrochem. Soc., Vol. 137, No. 6, June 1990, 1887-1891). Alkyl and hydroxyalkyl derivatives of ammonia offer the advantage of a lower vapor pressure and hence less of a problem with emissions in comparison to ammonia. Further components, such as complexing agents, surfactants, and stabilizers, can also be employed (see, for example, WO A 2006/039090).

The drawback of these solutions is the low etching back of the emitter surface layer within the contact time available in standard processes for solar cell manufacture, which usually is less than 1 min in a production line.

Described in EP A 1 843 389 is a sequence consisting of repeated chemical oxidation with subsequent dilute HF to remove the silicon oxide, so as to erode the uppermost highly doped emitter layers. Specified for chemical oxidation are ozone, ozone/H₂O, O₃/H₂O/HF, H—₂O₂, HNO₃, H₂SO₄, and NH₄OH at a temperature of between 20° C. and 90° C. This method is supposed to offer the advantage of a better degree of control of the emitter profile/phosphorus surface concentration created during diffusion with respect to oxidation. However, owing to chemical oxidation under the given conditions, an oxide layer with a thickness of only approximately 1 nm is produced. Several repetitions of the oxidation/HF sequence would be needed to erode the highly doped layer.

Described in EP A EP 0 731 495 as cleaning solutions for semiconductors in the framework of a modified RCA cleaning sequence are aqueous HF solutions containing ozone (and surfactant for improvement of the ozone solubility) or hydrogen peroxide.

An alternative possibility of avoiding the drawback of a high surface concentration of the dopant is offered by the development of the selective emitter. Thus, the production of a selective emitter via etching back of an emitter, diffused by conventional processes, in the regions between the metal contacts may be inferred from WO A 2009/013307. The regions beneath the metal contacts are protected by an etching barrier introduced beforehand. In the first step, a mixture made up of nitric acid and hydrofluoric acid is used for etching back for controlled production of a porous silicon layer. The etching progress is readily evident, because the porous silicon appears in various colors depending on the layer thickness. In the second step, the porous silicon is subjected to wet-chemical oxidation. Specified as oxidizing agents are HNO₃ and H₂SO₄. The removal of SiO₂ in dilute HF occurs subsequently.

A drawback of the mixed acid used is that it is difficult to control the formation of a homogenously porous Si layer by process engineering, so that—and as a consequence of inhomogeneous etching back—a strong scatter of the emitter layer resistance values over the wafer surface results.

DE A 20 2008 017 782 relates to a silicon solar cell, wherein a highly doped surface region is supposed to be etched-back. HF, HNO₃, and H₂SO₄ come into consideration as etching solution.

DD A 300 622 relates to an etching agent for anisotropic wet-chemical etching of silicon in order to produce X-ray masks, for example. The etching rate is adjusted such that an erosion of 1.9 μm/min occurs, for example.

DE A 10 2008 052 660 relates to a method for manufacturing a solar cell with two-stage doping. An inorganic protective layer is applied as mask to the surface being etched. Wet-chemical etching with an etching solution, containing nitric acid and hydrofluoric acid, then occurs, resulting in the creation of a porous layer, which is then removed by means of an alkaline etching solution.

The subject of US 2010/0126961 is a planarization of silicon thin-layer films. An alkaline etching solution, containing an oxidizing agent and, if necessary, a surfactant, is used to smooth any unevenness.

US A 2005/0022862 provides for a selective etching of regions of a solar cell by means of a concentrated KOH solution. Anisotropic etching occurs.

The present invention is based on the problem of providing a method for the wet-chemical etching back of a highly doped silicon layer in the form of a surface region of a crystalline solar cell emitter having a dopant concentration of >10¹⁸ atoms/cm³, in particular a dopant concentration of >10¹⁹ atoms/cm³, in which the drawbacks of prior art are avoided. At the same time, the possibility of carrying out a homogeneous etching back of the emitter should be afforded, for which process times that offer the possibility of not negatively influencing the manufacturing process in a process line may be employed.

To solve this problem, the invention provides essentially that an alkaline etching solution containing at least one oxidizing agent from the group peroxodisulfates, peroxomonosulfates, and hypochlorite is used as etching solution, with the respective content in the etching solution being 30 g/L (gram per liter) to 150 g/L, in particular 60 g/L to 100 g/L, when peroxodisulfates or peroxomonosulfates are used and, when hypochlorite is used, its content is 150 mL/L (millimeter per liter) to 750 mL/L, in particular 300 mL/L to 600 mL/L, of a solution containing 6%-14% active chlorine.

The use of the etching solution according to the invention offers the advantage that an isotropic and uniform etching back occurs, so that the texture structure produced before creation of the emitter is retained. Furthermore, the etching rate is higher than that of hydrogen peroxide-containing etching solutions employed in prior art. Hence, in particular, a stronger etching back of the solar cell emitter is possible within the contact times available in production units.

Another advantage of the alkaline etching solution according to the invention may be seen in the fact that porous silicon, which may have formed in process steps preceding the etching step, is completely removed.

Moreover, the alkaline etching solutions according to the invention make possible a fast removal of SiₓP_{y} and SiₓP_{y}O_{z} phases or of precipitates that may have formed in the course of diffusion.

In particular, it is provided that the alkaline component of the alkaline solution, containing an oxidizing agent, uses at least one component from the group of NaOH, KOH, ammonia, ammonia derivatives, tetraalkylammonium hydroxide, alkyl amines, alkanolamines, hydroxyalkyl alkyl amines, polyalkylene amines, and cyclic N-substituted amines, with the content of the alkaline component in the alkaline etching solution being 1 g/L to 100 g/L.

An example of ammonia derivatives is tetramethylammonium hydroxide. An example of alkyl amines is triethylamine. Examples of alkanolamines are mono-, di-, and triethanolamine. An example of hydroxyalkyl alkyl amines is choline. An example of polyalkylene amines is diethylenetriamine. Examples of cyclic N-substituted amines are N-methylpyrrolidine, N-methylpiperidine, and N-ethylpyrrolidone.

In order to enable prolonged use of the etching solution according to the invention, in particular for etching back of a highly doped emitter surface region, and to allow high throughput and at the same time achieve cleaning properties, the alkaline solution, which contains at least one oxidizing agent, should contain a complexing agent and/or a surfactant and/or a stabilizer. Coming into consideration as complexing agents, that is, complexing and chelating agents, are hydroxyphenols, amines, such as EDTA and DTPA, or di- and tricarboxylic acids, hydroxycarboxylic acids, such as citric acid or tartaric acid, polyalcohols, such as glycerol, sorbitol, and other sugars and sugar alcohols, phosphonic acids, and polyphosphates.

The oxidizing agent used in the etching solution according to the invention serves the function of an etching moderator in order to prevent too strong and anisotropic an etching attack on the etched-back, highly-doped emitter semiconductor layer. Known etching solutions, based on ammonia as alkaline component and using hydrogen peroxide as oxidizing agent, entail the drawback that the hydrogen peroxide decomposes very fast and non-selectively both on highly diffused substrates and on low-diffused substrates with oxide formation, that is, that the reaction is independent of the doping. Hence, known alkaline emitter solutions containing hydrogen peroxide entail the drawback of an emitter etching back that is too slow.

Furthermore, the etching solution according to the invention offers the advantage that porous silicon, which can form in the process steps preceding the etching step, is completely removed. If, by contrast, an alkaline etching solution containing hydrogen peroxide as oxidizing agent is employed, it is found that the removal of porous silicon is incomplete.

The erosion of a highly doped emitter layer region, which has a dopant concentration of at least >10¹⁸ atoms/cm³, in particular greater than 10¹⁹ atoms/cm³, can be detected through the change in the emitter layer resistance. The increase in the emitter layer resistance is a directly measurable parameter for emitter etching back. Comparisons between alkaline etching solutions containing hydrogen peroxide as oxidizing agent and etching solutions according to the invention have shown that, for a contact time of 35 s at a temperature of 50° C., the emitter layer resistance is increased by only approximately 1 ohm/sq. If, by contrast, a peroxodisulfate is used as oxidizing agent and NaOH as the alkaline component, it was found that, for a contact time of 35 and at a temperature of 50° C., the emitter layer resistance increases up to 9 ohm/sq. The cause of this may be that the peroxodisulfate reacts more slowly and preferably on highly diffused, particularly phosphorus-diffused substrates, with oxide formation. Owing to the oxide formation, the highly doped surface layer as the emitter is protected against too strong an anisotropic etching attack of the alkaline component. If, by contrast, the alkaline etching solution acts on low-diffused substrates, for which the concentration of the dopant is on the order of 10¹⁶ atoms/cm³, then the decomposition rate of the peroxodisulfate is lower, so that the substrates are attacked more strongly by the alkaline component.

Preferably, therefore, the alkaline etching solution according to the invention, containing peroxodisulfate as oxidizing agent, is used for etching back of a highly doped emitter layer. When peroxodisulfate is used, a faster emitter etching back occurs in comparison to the use of hydrogen peroxide, so that, as a result, shorter process times are possible. At the same time, a complete removal of porous silicon occurs.

Preferably used is an alkaline etching solution that contains NaOH as alkaline component and sodium peroxodisulfate as oxidizing agent, with the content of NaOH being between 5 and 10 g/L and the content of sodium peroxodisulfate being 5 to 330 g/L, preferably 50 to 150 g/L. Further constituents are water as well as, to the extent required, complexing agents, surfactants, and stabilizers, which can be used to modify the action of the etching solution.

Hypochlorite can be used as further oxidizing agent to moderate the etching attack of the alkaline component on the emitter.

The use of alkaline hypochlorite solution for texturing or polishing silicon wafers containing boron as base doping is indeed known (see Basu et al. “A cost effective multicrystalline silicon surface polishing solution with improved smoothness,” Solar Energy Materials and Solar Cells 93 (2009) 1743-1748). However, in this case, a highly concentrated solution is used at 80° C. (just below the decomposition temperature) and a contact time of 20 minutes for (non-selective) silicon etching.

In order to create a textured surface, a silicon erosion of approximately 500 mg (on a wafer that is 156×156 mm in size) is required. In order to create a polished surface, an erosion of approximately 1000 mg per wafer is required. This corresponds to the etching of a silicon layer of just 10-μm thickness on each side.

In accordance with the invention, a highly doped surface region of a silicon substrate, in particular the emitter of a solar cell, is etched back by using a dilute hypochlorite solution at low temperature in the range of between 35° C. and 60° C., resulting in the erosion of approximately 1 mg for a wafer that is 156×156 mm in size, that is, less than 10 nm on each side.

Therefore, the invention is characterized in that a layer of thickness d, with d 15 nm, in particular d 10 nm, especially preferably 2 nm d 7 nm is etched back isotropically and uniformly, following the surface topography.

The use of hypochlorite exploits the property that hypochlorite reacts preferably on highly diffused, in particular phosphorus-diffused substrates with oxide formation. As a result of oxide formation, the emitter is protected against too strong an etching attack of the alkaline component. On low-diffused substrates, the decomposition rate of hypochlorite is lower; these substrates are etched faster by the alkaline component. Any porous silicon that is present is completely removed.

Another advantage of the alkaline etching solution containing at least one oxidizing agent may be seen in the fact that a selective removal of the separate phases of composition SiₓP_{y} and SiₓP_{y}O_{z} that are formed and crystallize out, appearing in the course of diffusion in the form of needle-shaped precipitates, is made possible.

The alkaline etching solution according to the invention, which contains hypochlorite as oxidizing agent, can have the aforementioned alkaline components. The use of hypochlorite as oxidizing agent offers the same advantages as does the use of peroxodisulfates and peroxomonosulfates, because a fast and uniform erosion of the highly doped surface layer likewise occurs, with additionally removal of the SiₓP_{y} and SiₓP_{y}O_{z} phases and precipitates. In this process, the removal is quite fast, so that the precipitates are cleaned out after only a few seconds, with the solution preferably having a temperature of approximately 40° C.

The removal of SiₓP_{y} and SiₓP_{y}O_{z} phases or precipitates therefore occurs within a time that does not entail any nominal etching back of the highly doped silicon layer, that is, the regularly phosphorus-diffused silicon layer. This can be followed by measurement of the emitter layer resistance.

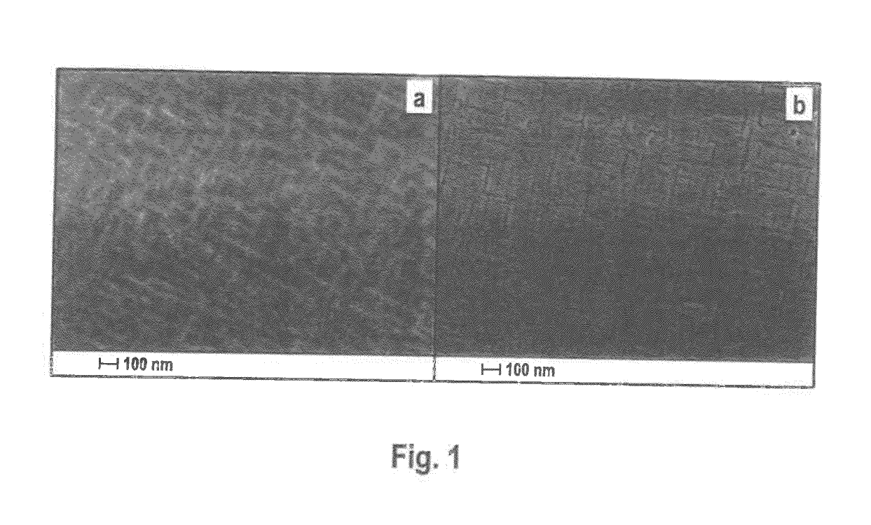

Shown in FIG. 1 are pictures of silicon substrates produced according to the Czochralski process, which are oriented in the <110> direction. Seen in the left picture are the precipitates on the emitter surface. If an etching solution according to the invention, containing NaOH as alkaline component and hypochlorite as oxidizing agent, is used, the precipitate is etched away. This is manifested in the right picture by empty pits.

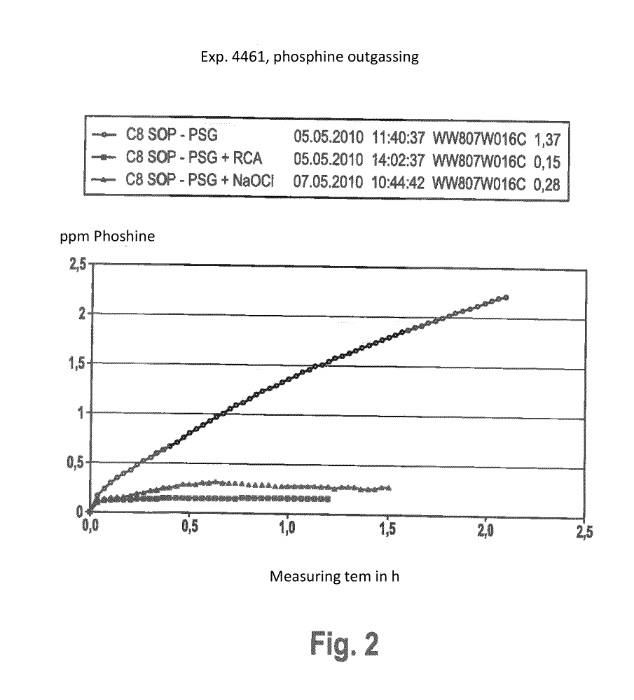

The proportion of the SiₓP_{y} and SiₓP_{y}O_{z} phases or the precipitates can be determined by measurement of phosphine outgassing. Phosphine is formed by slow hydrolysis of the precipitates in air, that is, by reaction with moisture in the air. Corresponding measurements may be taken from FIG. 2. Thus, FIG. 2 shows the cumulative phosphine outgassing after standard cleaning (empty squares) in comparison to standard cleaning with additional RCA sequence (solid squares) and after standard cleaning with alkaline hypochlorite solution, that is, with an alkaline etching solution in accordance with the invention containing hypochlorite as oxidizing agent. The phosphine outgassing is represented by solid triangles. It could be found that the reduction of phosphine outgassing after 1 minute at a temperature of approximately 40° C., when an etching solution according to the invention in the form of an alkaline hypochlorite solution is used, is comparable to the reduction by RCA sequence. The parameters used were 10 min of SC1 at 60° C., rinsing, and 10 min of SC2 at 80° C.

A corresponding aqueous alkaline solution according to the invention preferably has the following composition:

NaOH: 1 g/L-100 g/L, preferably 5 g/L-10 g/L

sodium hypochlorite solution (containing 6%-14% active chlorine): 150 mL/L-750 mL/L, preferably 250 mL/L-300 mL/L, with possibly KOH being included as an additional alkaline component.

The etching solution according to the invention can be employed in vertical units and/or in horizontal units.

Furthermore, it should be noted that the highly doped silicon layer can contain phosphorus, arsenic, boron, aluminum, or gallium as dopant, depending on the base doping.

Furthermore, the invention is characterized in that the etching solution according to the invention is used for the production of a selective emitter.

Moreover, the invention is characterized by the use of one of the aforementioned etching solutions for etching back the emitter, with a metal layer being deposited at least selectively onto the surface of the crystalline solar cell by chemical deposition or electrodeposition of a nickel/silver or nickel/copper layer or by physical vapor deposition methods after etching back of the emitter. When a vapor deposition method is used, a titanium/palladium/silver layer, in particular, is deposited.

The field of application of the invention is the manufacture of solar cells made of silicon. Therefore, the invention is characterized by a solar cell, the emitter of which is etched-back by using measures that have been described above.

Further details, advantages, and features of the invention ensue from the following examples.

### EXAMPLE 1

In an inline diffusion process, phosphorus was diffused into p-type silicon wafers. The concentration of phosphorus was greater than 10¹⁹ atoms/cm³. The boron concentration amounted to approximately 10¹⁶ atoms/cm³. After diffusion, the wafers were subjected to an etching sequence in a horizontal unit, consisting of removal of phosphosilicate glass in dilute hydrofluoric acid, chemical edge isolation, and treatment in the alkaline solution according to the invention and treatment in an acidic cleaning solution.

The aqueous alkaline solution according to the invention had the composition:

NaOH 12 g/L

sodium peroxodisulfate 65 g/L.

The contact time was 30 s at a temperature of 50° C. The measurement of the emitter layer resistance afforded a difference of 9 ohm/sq between the layer resistance after diffusion and after the described etching sequence. Of this, 5 ohm/sq may be ascribed to the action of the alkaline solution and the remainder is caused by the other solutions of the etching sequence.

An identical process sequence, although with hydrogen peroxide-containing solution instead of the solution containing peroxodisulfate, afforded an emitter etching back of 5 ohm/sq. Residues of porous silicon were not completely removed.

### EXAMPLE 2

In a diffusion process, phosphorus was diffused into silicon wafers in a concentration greater than 10¹⁹ atoms/cm³. The wafers were p-type silicon wafers with boron as base doping in a boron concentration of about 10¹⁶ atoms/cm³. After diffusion, the phosphosilicate glass formed was removed in dilute hydrofluoric acid.

The wafers were then etched out in the following etching solution according to the invention, the solution being present in a glass beaker:

The aqueous solution has the following composition:

tetramethylammonium hydroxide: 10 g/L

ammonium peroxodisulfate: 50 g/L.

The contact time was 180 seconds at 45° C. Layer resistance after diffusion: 45.2 ohm/sq.

Layer resistance after the above-mentioned etching sequence: 56.7 ohm/sq.

Hence, there is a difference of 11.4 ohm/sq in the emitter layer resistance.

For comparison, an aqueous solution of the following composition was used:

tetramethylammonium hydroxide: 10 g/L

hydrogen peroxide: 10 g/L.

The contact time was 180 seconds at 45° C. The same test setup and the same starting material were used. The difference in the emitter layer resistance was 2.3 ohm/sq.

### EXAMPLE 3

In the same test setup as in Example 2 and with the same starting material, the following aqueous etching solution was used:

diethylenetriamine: 30 g/L

ammonium peroxodisulfate: 35 g/L.

Contact time of 180 seconds at 35° C. The difference in the emitter layer resistance was 8.1 ohm/sq.

### EXAMPLE 4

The following aqueous etching solution was used with the same test setup as in Example 2 and with the same starting material.

NaOH: 15 g/L

sodium hypochlorite solution (containing 6-14% active chlorine): 250 mL/L.

Contact time of 1 minute at 40° C.

Layer resistance after diffusion: 53.5 ohm/sq, layer resistance after removal of phosphosilicate glass and after treatment in the hypochlorite solution: 61.0 ohm/sq. Hence, there is a difference in the emitter layer resistance of 7.5 ohm/sq.

### EXAMPLE 5

The following aqueous etching solution, containing a much higher hypochlorite concentration, was used in the same test setup as in the preceding example and with the same starting material:

NaOH: 15 g/L

sodium hypochlorite solution (containing 6-14% active chlorine): 750 mL/L.

Contact time of 1 minute at 40° C.

Layer resistance after diffusion: 53.6 ohm/sq, layer resistance after the above-mentioned etching sequence: 55.6 ohm/sq.

The difference in the emitter layer resistance before and after treatment in dilute HF and in the alkaline solution containing hypochlorite is very small. Owing to the high concentration of the oxidizing agent, the emitter etching back is slowed. In spite of the low etching back, the precipitates were cleaned out. This could be detected on the basis of minimal phosphine outgassing.

### EXAMPLE 6

The same aqueous solution, the same test setup, and the same starting material as in Example 2 were used.

The contact time was 10 minutes at 70° C. The emitter was strongly etched back to 85 ohm/sq.

The etching erosion was 62 mg. This corresponds to a silicon layer thickness of 1.1 μm for a wafer with an area of 156 mm×156 mm.

The low-doped back side was etched markedly more strongly than the emitter side. This was directly evident in the gas evolution.

The emitter is only 200 nm to 1000 nm thick for a total thickness of the silicon wafer of approximately 100 μm to 200 μm. Here, wafers with an emitter that was approximately 350 nanometers in thickness were used. If the reaction on both sides, that is, on the highly doped front side and the low-doped back side, proceeds at an equal rate, the emitter would have been completely etched away.

1-13. (canceled)

14. A method for the wet-chemical etching back of a surface region of an emitter of a crystalline solar cell in an etching solution, the silicon layer having a dopant concentration of greater than 10¹⁸ atoms/cm³, the method comprising:
using an alkaline etching solution comprising at least one oxidizing agent selected from the group consisting of peroxodisulfates, peroxomonosulfates, and hypochlorite to etch back the surface region, the at least one oxidizing agent comprising peroxodisulfates or peroxomonosulfates having a content in the alkaline etching solution between 30 g/L and 150 g/L or hypochlorite having a content in the alkaline etching solution between 150 mL/L to 750 mL/L of a solution containing 6% to 14% active chlorine.

15. The method according to claim 14, wherein the at least one oxidizing agent comprising peroxodisulfates or peroxomonosulfates has a content of between 60 g/L to 100 g/L.

16. The method according to claim 14, wherein the at least one oxidizing agent comprising hypochlorite has a content in the alkaline etching solution between 300 mL/L to 600 mL/L.

17. The method according to claim 14, wherein the alkaline etching solution has an alkaline component selected from the group consisting of NaOH, KOH, ammonia, ammonia derivatives, tetraalkylammonium hydroxide, alkyl amines, alkanolamines, hydroxyalkyl alkyl amines, polyalkylene amines, and cyclic N-substituted amines, with the content of the alkaline component in the alkaline etching solution being 1 g/L to 100 g/L

18. The method according to claim 17, wherein the content of the alkaline component in the alkaline etching solution is 5 g/L to 10 g/L.

19. The method according to claim 14, wherein the alkaline etching solution further comprises at least one component selected from the group consisting of complexing agents, surfactants, and stabilizers.

18. The method according to claim 14, wherein the alkaline etching solution further comprises a complexing agent selected from the group consisting of hydroxyphenols, amines, hydroxycarboxylic acids, polyalcohols, phosphonic acids, and polyphosphates.

19. The method according to claim 14, wherein the alkaline etching solution comprises a dilute hypochlorite solution with a composition comprising NaOH: 1 g/L to 100 g/L, and sodium hypochlorite solution (in a solution containing 6% to 14% active chlorine): 150 mL/L to 750 mL/L

20. The method according to claim 19, wherein the sodium hypochlorite solution, in a solution containing 6% to 14% active chlorine, comprises 250 mL/L to 300 mL/L.

21. The method according to claim 19, further comprising KOH.

22. The method according to claim 14, wherein the alkaline etching solution comprises sodium peroxodisulfate as the oxidizing agent with a composition comprising NaOH: 1 g/L to 100 g/L, sodium peroxodisulfate: 30 g/L to 150 g/L, and at least one component selected from the group consisting of KOH, ammonia or ammonia derivatives, tetraalkylammonium hydroxide, amines, peroxodisulfate salts, ammonium peroxodisulfates, potassium peroxodisulfates, peroxomonosulfates, and potassium peroxomonosulfate.

23. The method according to claim 14, further comprising utilizing the etching solution in unit selected from the group consisting of a vertical unit, horizontal units, and combinations thereof.

24. The method according to claim 14, wherein the highly doped silicon layer comprises, as a dopant, a material selected from the group consisting of phosphorus, arsenic, boron, aluminum, and gallium.

25. The method according to claim 14, wherein the step of using the alkaline etching solution comprises isotropically etched back a layer of thickness less than or equal to 15 nm.

26. The method according to claim 25, wherein the layer of thickness less than or equal to 7 nm and more than or equal to 2 nm.

27. The method according to claim 14, further comprising, after etching back the surface region, applying a metal layer at least selectively onto the surface region by a method selected from the group consisting of chemical deposition, electrodeposition, and physical vapor deposition.

28. The method according to claim 27, wherein the metal layer is selected from the group consisting of a nickel/silver layer, a nickel/copper layer, and a titanium/palladium/silver layer.

29. A solar cell having an emitter etched back according to the method of claim 14.
